(19) United States
(12) Patent Application Publication
(10) Pub. No.: US 2006/0103002 A1
(43) Pub. Date: May 18, 2006

(54) Semiconductor packages with asymmetric connection configurations

(76) Inventors: Mee-Hyun Ahn, Suwon-si (KR); Jong-Joo Lee, Suwon-si (KR); Yong-Jae Lee, Seongnam-si (KR)

Correspondence Address: HARNESS, DICKEY & PIERCE, P.L.C., P.O. BOX 8910, RESTON, VA, 20195, US

(21) Appl. No.: 11/261,569

(22) Filed: Oct. 31, 2005

(30) Foreign Application Priority Data
Nov. 12, 2004 (KR) 2004-0092447

(51) Int. Cl. H01L 23/52

(52) U.S. Cl. 257/692

(57) ABSTRACT

Provided are semiconductor devices and methods for configuring lead frames and/or device bonding pads to provide for the independent adjustment of the electrical characteristics of both fixed voltage lines, e.g., V_{dd} and Vₛₛ, and the signal lines, e.g., command, clock, data and address. In particular, the invention provides for adjusting the relative sizing of leads corresponding to fixed voltage lines and signal lines for increasing the relative capacitance on the fixed voltage lines to improve their stability will reducing the noise on the signal lines. The invention may be utilized with a variety of package configurations including lead-on-chip LOC configurations, more conventional quad flat pack QFP configurations in which the leads do not extend past the perimeter of the semiconductor chip or hybrid configurations in which some leads do extend past the perimeter of the semiconductor chip and across the active surface.

### PRIORITY STATEMENT

This U.S. non-provisional application claims benefit of priority under 35 U.S.C. § 119 from Korean Patent Application No. 2004-0092447, filed on Nov. 12, 2004, the entire contents of which are incorporated herein by reference.

### BACKGROUND OF THE INVENTION

1. Field of the Invention

The invention relates to lead frames used for connecting electrical signals to packaged integrated circuits including those lead frames configured to extend over an active surface of the integrated circuits, also known as a lead on chip or LOC configuration. By modifying the relative configurations of the fixed voltage leads, e.g., ground and power, and the associated signal leads, lead frames according to the invention generally reduce connection capacitance and the likelihood of coupling between adjacent signal lines and improve the stability of the fixed voltage leads.

2. Description of the Related Art

Conventional LOC packaging techniques for high-speed dynamic random access memory DRAM devices typically include a number of constant or fixed voltage leads, typically V_{dd} and Vₛₛ, and a larger number of signal leads which extend over the active surface of the integrated circuit chip and terminate in a bonding region. The leads may be attached to the active surface of the semiconductor chip with a pattern formed from double-sided adhesive tape and/or other suitable adhesives and/or encapsulants. The bond pads are typically arranged in a single row along the central longitudinal axis of the chip and are connected to corresponding bonding regions of the leads using bonding wires of generally equal length.

Interconnection and packaging issues are certain of the factors that determine both the number of circuits and/or functions that can be integrated on a single semiconductor chip and the resulting performance of that chip. The importance of these issues has tended to increase as advances in both chip design and imaging and processing methods have continued to reduce the sizes of transistors and/or enlarge chip dimensions.

Within the semiconductor industry, there is a realization that merely increasing the processing speed of the active regions formed on a semiconductor chip will not necessarily translate into system processing improvements. In order for the, benefits of improved circuitry to be realized in a fast system, the chip must be supported with fast and reliable connections. Indeed, it is the connections to the semiconductor chip, in conjunction with the external structures, for example, solder ball, solder bumps, and pins, connections, that allow the semiconductor chip to cooperate within a system.\

FIGS. 1A and 1B illustrate a plan view and a cross-sectional view along line B-B of FIG. 1 A respectively of a conventional semiconductor device 310 having a LOC configuration with a semiconductor chip 311, for example a DRAM chip. The semiconductor chip 311 has a center-pad configuration in which all of the chip pads 313 are arranged in a single row that is generally centered on the active surface of the semiconductor chip. At least a portion of the bottom surfaces of the leads 321 are attached to the active surface of the semiconductor chip by adhesive tape patterns 325. The chip pads 313 are connected to the corresponding leads 321 using a plurality of bonding wires 331 of similar length.

The semiconductor chip, leads and bonding wires can then be encapsulated with a molding compound 335. The various chip pads can be generally categorized or grouped by the function of the associated circuitry into signal pads 313a (command, address and input/output), power pads 313b and ground pads 313c. The leads 321 and bonding wires 331 can be categorized or grouped in a same manner. FAs reflected in FIGS. 1A and 1B, the structure of the various connections is very similar, e.g., the length and area of the leads 321 is substantially the same for each of the connections. Similarly, the length of the bonding wires 331 is substantially the same for each of the connections. Accordingly, each of the connections will exhibit similar electrical characteristics, particularly with respect to capacitance and inductance.

As the size of the various connection components decreases and/or the speed of the associated semiconductor device increases with any conductive line carrying a signal the electromagnetic and electrostatic fields generated by the various conductors can interfere with the proper functioning of the device. In particular, the electromagnetic and electrostatic fields may affect the signals carried on both the active signal line and in signal lines adjacent the base signal line unless some form of compensation is used. One method used to address this condition involves arranging ground planes adjacent the signal lines to suppress cross-talk between adjacent signal lines.

As will be appreciated, electromagnetic and/or electrostatic coupling between signal lines, also referred to as “cross-talk,” is undesirable because it increases the load of the signal lines and may create noise and/or signal delays. Factors affecting cross-talk include the surface area of the active signal line directed towards an adjacent signal line, which includes signal line length, the distance separating the active and adjacent signal lines and the dielectric constant (εᵣ) of the insulating material(s) between the signal lines.

Even when the active signal line is sufficiently isolated from adjacent signal lines to reduce cross-talk to tolerable levels, self-inductance can remain an issue. Self-inductance is the induction of a voltage in a conductor when the current flowing through the conductor changes. In cases of self-inductance, the magnetic field created by a changing current in the conductor induces a voltage in the same conductor and, like cross-talk can increases the load of the signal lines and may create noise and/or signal delays.

Another consideration in packaging design is the varying external line lengths between bond pads or other contacts on a semiconductor die and the connections of the substrate on which the die is mounted. The conventional wisdom suggests that the system speed will be increased by utilizing the shortest possible signal lines to reduce the distance the signal needs to travel. Accordingly, signal lines provided on a semiconductor die, circuit board or other carrier substrate, are typically configured to reduce signal line length to the extent possible, taking into consideration the relevant design rules and accommodating the overall layout of all the necessary signal line paths. Thus, although signal lines will tend to provide as direct a path as possible between their origin and their destination, particularly for more highly integrated devices there will necessarily be some variation to accommodate other signal lines and/or other components.

For a given semiconductor device, therefore, the signal line lengths will tend to have some variation in length and/or total area. Because the load of the signal line depends, in part, on the length of the signal line, the loads associated with the signal lines will vary accordingly. Furthermore, as a result of the varying signal line lengths, signals traveling on those signal lines have varied travel times and associated delays that will tend to limit the speed at which the device can be operated. Significant mismatches between the properties of signal lines may cause undesirable signal reflections and delays, making it desirable to have the signal lines associated with a semiconductor device configured to produce relatively equal impedance loads.

Therefore, it is desirable to produce a semiconductor device in which the signal lines exhibit relatively matched characteristic loads and reduced capacitance without requiring the use of additional layers of metallization, capacitors and/or inductors. Further, it is also desirable to produce a semiconductor device in which the signal lines, i.e., the combination of lead and bonding wire that form the connection between the semiconductor device and the external circuit, that will be subjected to varying voltages and currents have a first configuration while the fixed voltage lines, i.e., the ground and high voltage conditions have a second configuration to improve the overall operation of the semiconductor device.

### BRIEF SUMMARY OF THE INVENTION

The detailed description provided below discloses combinations of lead frames, bonding wires and bonding pad configurations for manufacturing semiconductor devices that include a semiconductor chip having an upper surface with an outer perimeter and a first plurality of bonding pads arranged on the upper surface; a leadframe having a first plurality of fixed voltage leads and a second plurality of signal leads; and a plurality of bonding wires connecting a terminal portion of each of the leads to corresponding ones of the bonding pads, wherein, the bonding wires connecting the first plurality of fixed voltage leads to the corresponding bonding pads have an average length B_{PG}; the bonding wires connecting the second plurality of signal leads to the corresponding bonding pads have an average length B_{S}; and further wherein B_{PG} and B_{S} satisfy the relationship B_{PG}<B_{S}.

In some embodiments of the invention, the semiconductor devices may exhibit a ratio between the average lengths B_{PG} and B_{S} of from 1:2 to 1:5. In other configurations the first plurality of bonding pads may be arranged in a single row, in two rows, in three rows or even more rows. The rows of bonding pads may be arranged along a longitudinal axis of the semiconductor chip, may be symmetric about the axis, may be perpendicular to the axis or may be provided in one or more non-linear configurations.

In other embodiments of the invention, portions of the first plurality of fixed voltage leads may extend inwardly from the perimeter of the semiconductor chip and over the upper surface of the semiconductor chip by an average length L_{PG}; and portions of the second plurality of signal leads extend inwardly from the perimeter of the semiconductor chip and over the upper surface by an average length L_{S}; and further wherein L_{PG} and L_{S} satisfy the relationship L_{PG}>L_{S}. In other embodiments of the invention, the various relative dimensions may be such that the relationship B_{PG}+L_{PG}=B_{S}+L_{S} or the relationship B_{PG}+L_{PG}>B_{S}+L_{S} is satisfied.

In other embodiments of the invention, portions of the first plurality of fixed voltage leads may extend inwardly from the perimeter of the semiconductor chip and over the upper surface by an average length L_{PG}; and no portion of the second plurality of signal leads extends inwardly from the perimeter of the semiconductor chip. Conversely, in other embodiments of the invention portions of the first plurality of fixed voltage leads may extend inwardly from the perimeter of the semiconductor chip and over the upper surface by an average length L_{PG} with a subset of leads of the second plurality of signal leads not including any portion that extends inwardly from the perimeter of the semiconductor chip. Or a subset of the first plurality of fixed voltage leads may not include any portion that extends inwardly from the perimeter and across the active surface of the semiconductor chip in combination with a subset of leads of the second plurality of signal leads do not include any portion that extends inwardly from the perimeter of the semiconductor chip.

The various combinations of the lead configuration and the bonding wire configuration provide embodiments of the invention in which portions of first plurality of fixed voltage leads extend inwardly from the perimeter of the semiconductor chip and over a first portion of the upper surface, thereby producing an average capacitance C_{PG} and in which portions of the second plurality of signal leads extend inwardly from the perimeter of the semiconductor chip and over a second portion of the upper surface, thereby producing an average capacitance C_{S}; and further wherein C_{PG} and C_{S} satisfy the relationship C_{PG}>C_{S}. Indeed, the ratio of the average capacitances C_{PG} and C_{S} may be from about 2:1 to 5:1.

As provided in more detail below, the invention allows for the independent adjustment of the electrical properties of the fixed voltage lines and the signal lines, particularly with respect to capacitance and inductance, for improving the performance and stability of the resulting devices.

### BRIEF DESCRIPTION OF THE DRAWINGS

The example embodiments of the invention will be readily understood with reference to the following detailed description thereof provided in conjunction with the accompanying drawings, wherein like reference numerals designate like structural elements.

FIGS. 1A and 1B illustrate a plan view and a cross-sectional view respectively of a semiconductor device having a conventional LOC configuration;

FIGS. 2A and 2B illustrate a plan view and a cross-sectional view respectively of a semiconductor device having a LOC configuration in accord with an example embodiment of the invention;

FIGS. 3A and 3B illustrate a plan view and a cross-sectional view respectively of a semiconductor device having a LOC configuration in accord with another example embodiment of the invention;

FIGS. 4A and 4B illustrate a plan view and a cross-sectional view respectively of a semiconductor device having a quad flat pack configuration in accord with an example embodiment of the invention; and

FIG. 5 illustrates a plan view of a semiconductor device having a LOC configuration in accord with another example embodiment of the invention.

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION OF EXAMPLE EMBODIMENTS

In many semiconductor devices, the connection between the actual solid state device and the external electrical connections pass through a combination of a lead and a bonding wire. The lead is typically a relatively planar conductive pattern formed from a conductive layer that includes a bonding region. Bonding wires are typically fine, generally cylindrical wires that are connected via a process such as ball-bonding or stitch-bonding, to form an arched connector between the bonding region on a lead and a chip pad provided on the active area of the semiconductor chip. The chip pads are, in turn, connected internally to the underlying semiconductor circuit elements.

Each of these two components, the lead and the bonding wire, make different contributions to the overall electrical performance of the connection as a result of their different configuration and placement. For example, the bonding wires tend to be relatively narrow and positioned well above the active surface of the semiconductor chip. Conversely, the leads are relatively wide and are typically separated from the active surface of the chip by a relatively thin layer of insulating material.

Accordingly, bonding wires tend to make a relatively smaller contribution to the overall capacitance of the connector while the leads tend to make a relatively larger contribution to the overall capacitance of the connector. Conversely, bonding wires tend to make a relatively larger contribution to the overall inductance of the connector while the leads tend to make a relatively smaller contribution to the overall inductance of the connector. These general tendencies are summarized below in Table 1.

TABLE 1

| | Bonding Wires | Leads |
|---|---|---|
| Width | narrow | wide |
| Spacing to Active Surface | large | small |
| Capacitance | small | large |
| Inductance | large | small |

In high frequency semiconductor devices, for example DRAM devices, increasing capacitance and reducing inductance will tend to reduce noise on fixed voltage connections, e.g., power and ground connections. Conversely, reducing capacitance while continuing to maintain satisfactory inductance performance tends to improve the high speed operation of signal connections.

Semiconductor devices manufactured according to an example embodiment of the invention utilize asymmetric connection configurations whereby the fixed voltage connections and the signal connections have different configurations to improve the overall operation of the resulting high frequency semiconductor device.

### First Embodiment

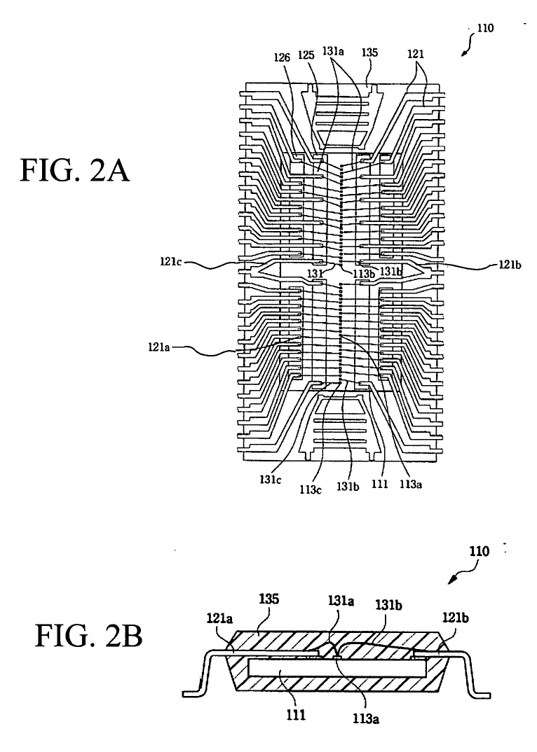

FIGS. 2A and 2B illustrate a plan view and a cross-sectional view respectively of a semiconductor device having a LOC configuration in accord with an example embodiment of the invention. As illustrated in FIG. 2A, the semiconductor device includes a semiconductor chip 111 having an active surface, for example a DRAM device, having a center-pad configuration. The semiconductor chip is attached on a bottom surface of leads 121 by adhesive tapes 125, 126. Chip pads 113 are connected to the leads by bonding wires 131. The semiconductor chip, the leads and the bonding wires are encapsulated within a molding compound 135.

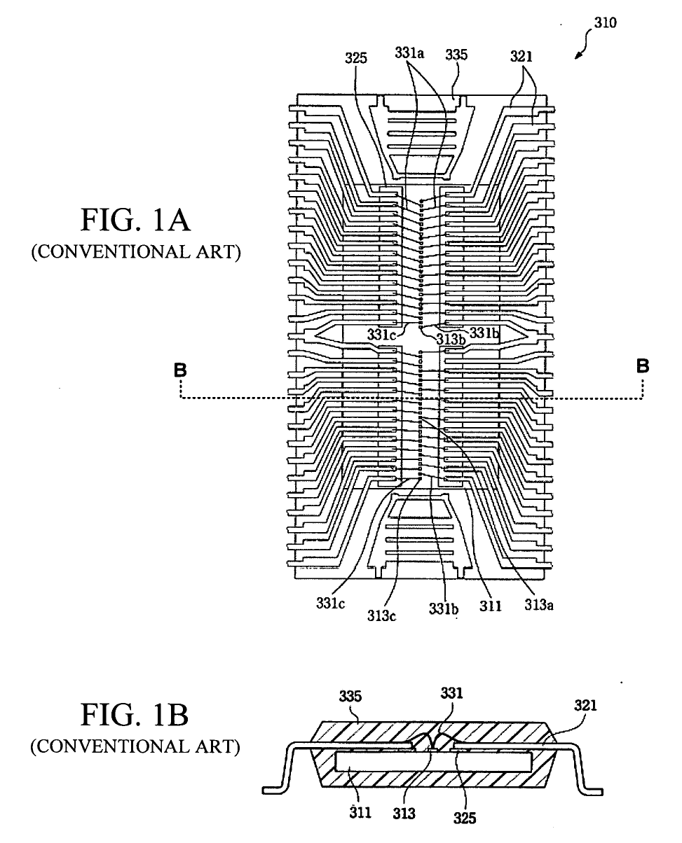

As illustrated in FIG. 2A, particularly in comparison with the device illustrated in FIG. 1A, the semiconductor device having a LOC configuration in accord with an example embodiment of the invention includes two different connector configurations. The first configuration is utilized to form electrical connections to the various signal bonding pads 113a and includes a lead 121a having a relatively short extension across the active surface of the semiconductor chip 111 and a bonding wire 131a that has a relatively long extension across the active surface to complete the connection. The second configuration is utilized to form electrical connections to the various fixed voltage bonding pads 113b, 113c and includes a lead 121b, 121c having a relatively long extension across the active surface of the semiconductor chip 111 and a bonding wire 131b, 131c having a relatively short extension across the active surface to complete the connection. Also, in addition to the variations in length, those leads corresponding to fixed voltage lines may be relatively wider than those corresponding to signal lines, thereby further increasing the average difference in capacitance and further stabilizing the fixed voltage lines.

With respect to the various structural elements forming the connections, the various suffixes indicate the type of connection being made with the “a” pads, leads and bonding wires relating to signal lines (command, address and input/output), the “b” elements relating to power (V_{dd}) connections and “c” elements relating to ground (Vₛₛ) connections, the “b” and “c” lines corresponding to “constant” or “fixed voltage” lines. As will be appreciated by those skilled in the art, the term “fixed voltage” does not refer to or imply a truly fixed voltage, only that the anticipated or designed voltage on the referenced line or pin has a nominal value near one of the designated “rail” voltages or potentials, either high or low, for a particular device.

### Second Embodiment

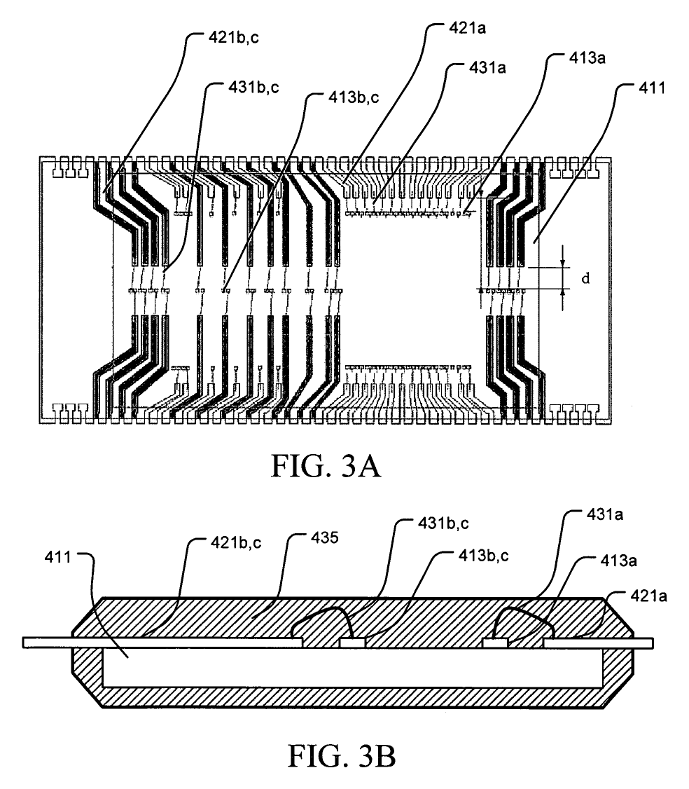

FIG. 3A illustrates a plan view and of a semiconductor device having a LOC configuration in accord with another example embodiment of the invention. As illustrated in FIG. 3A, the semiconductor device includes a semiconductor chip 411 having an active surface, for example a DRAM device, having three separate rows of bonding pads, including a first plurality of bonding pads 413b, 413c arranged in a center-pad configuration and a second plurality of bonding pads 413a arranged in two additional rows positioned between the center-pad row and opposite edges of the semiconductor chip.

The semiconductor device also includes a first plurality of leads 421a that extend a first average length L_{S} over the active surface of the semiconductor chip 411 and a second plurality of leads 421b, 421c that extend a second average length L_{PG} over the active surface, where L_{S}<L_{PG}. The various pluralities of leads 421a-c can be attached to the active surface of the semiconductor with one or more adhesive regions or tape patterns (not shown). The semiconductor device also includes a first plurality of bonding wires 431 a that extend a first average length B_{S} over the active surface of the semiconductor chip 411 and a second plurality of leads 431b, 431c that extend a second average length B_{PG} over the active surface, where B_{S} may be greater than or approximately equal to B_{PG}. The minimum length of the bonding wires 431a-c will be determined by the design rules for the package being manufactured and the capability of the particular wire bonding equipment utilized. In most instances, it is anticipated that the minimum length of the bonding wires will be in a range from about 0.75 to 1.0 mm. Also, in addition to the variations in length, those leads corresponding to fixed voltage lines may be relatively wider than those corresponding to signal lines, thereby further increasing the average difference in capacitance and further stabilizing the fixed voltage lines.

### Third Embodiment

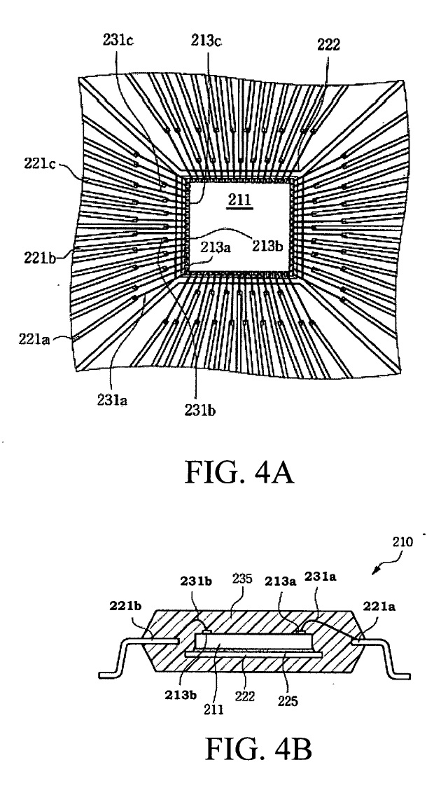

As illustrated in FIGS. 4A and 4B, another example embodiment of the invention can be utilized in manufacturing an improved QFP (Quad Flat Package) using an asymmetric configuration similar to that detailed above in connection with the first example embodiment. As illustrated in FIG. 4A, although none of the leads extend over the active surface of the semiconductor chip 211, those leads associated with the fixed voltage lines 221b, 221c extend closer to the edge of the semiconductor chip while those associated with the signal lines 221a a terminated further from the edge of the semiconductor chip. Also, in addition to the variations in length, those leads corresponding to fixed voltage lines may be relatively wider than those corresponding to signal lines, thereby further increasing the average difference in capacitance and further stabilizing the fixed voltage lines.

Accordingly, the bonding wires 231b, 231c that connect the fixed voltage leads to the corresponding peripheral bonding pads 213b, 213c are relatively short. Conversely, the bonding wires 231a that connect the signal leads to the corresponding peripheral bonding pads 213a are relatively long. As illustrated more clearly in the cross-sectional view provided in FIG. 4B, the bottom or backside surface of the semiconductor chip 211 can be attached to a die pad region 222 provided on the lead frame with a suitable adhesive or adhesive tape. Because no portion of the leads 221 extends over the active surface of the semiconductor chip 211 the differential capacitance between the fixed voltage leads and the signal leads may not be as large as that exhibited in a LOC configuration. The difference, however, may still be reflected in improved stability in the fixed voltage leads and reduced noise in the signal leads.

### Fourth Embodiment

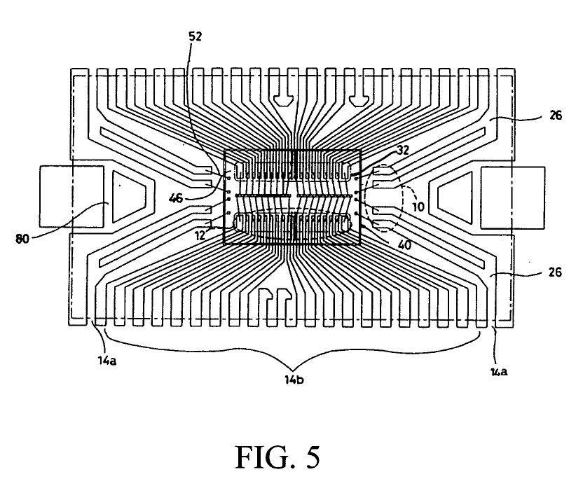

FIG. 5 illustrates another example embodiment of the invention in which both LOC and “normal” lead configurations are combined in a hybrid lead frame package. As illustrated in FIG. 5, the package may include a plurality of LOC-type leads 12 that extend across a portion of the active surface of the semiconductor device. Depending on the chip pad configuration, these LOC-type leads 12 may be configured to provide asymmetric connections for the fixed voltage lines and the signal lines utilizing the configurations illustrated in FIGS. 2A and 3A and detailed above in the text associated with these figures in the first and second embodiments. Similarly, the normal-type leads 10 may be configured to provide asymmetric connections for the fixed voltage lines and the signal lines utilizing the configurations illustrated in FIG. 4A and detailed above in the text associated with that figure in the third embodiment.

Similarly, depending on the design of the particular semiconductor chip 40, either the normal-type leads 10 or the LOC-type leads 12 may be configured as only signal leads or only fixed voltage leads with the remaining leads providing the remaining signal and/or constant voltage configurations necessary to achieve the desired functionality of the semiconductor device. Also, in addition to length, those leads corresponding to fixed voltage lines may be relatively wider than those corresponding to signal lines, thereby further increasing the average difference in capacitance and further stabilizing the fixed voltage lines.

As will be appreciated by those skilled in the art, various changes in or combinations of the embodiments detailed above and illustrated in the accompanying figures may be made without departing from the spirit and scope of the invention. For example, in the first embodiment, there is no requirement that the chip pads be aligned in a single row near or on the longitudinal axis of the semiconductor chip and may be offset toward one side of the semiconductor chip in a generally parallel configuration or may incorporate some rotational offset as well. Similarly, although as illustrated, the third embodiment includes three distinct and generally parallel rows of chip pads, these pads may be arranged in two or more rows in a more central area of the chip or may be separated into further groupings which may assume non-linear configurations.

As will be appreciated, such alternative configurations may present further challenges during the alignment and wire bonding processes. Similarly, the various example embodiments detailed above may be adapted for multi-chip packages and utilized for a wide range of semiconductor devices including, for example, DRAM, SRAM, Flash, system LSI, and ASIC. Regardless of the particular semiconductor chip or package format, the invention may be utilized to adjust the relative capacitance and inductance on signal lines and fixed voltage lines independently, thereby improving the overall performance of the resulting device.

Although example, non-limiting embodiments of the invention have been described in detail hereinabove, it should be understood that many variations and/or modifications of the basic inventive concepts herein taught, which may appear to those skilled in the art, will still fall within the spirit and scope of the example embodiments of the invention as defined in the appended claims. Further as used herein, the term “subset” can include the entire set, i.e., it does not have to represent fewer than all of the members of the “set.”

We claim:

1. A semiconductor device comprising:
a semiconductor chip having an upper surface with an outer perimeter and a first plurality of bonding pads arranged on the upper surface;
a leadframe having a first plurality of fixed voltage leads, including leads for providing a voltage at a ground voltage and a plurality of leads for providing a voltage offset from the ground voltage, and a second plurality of signal leads; and
a plurality of bonding wires connecting a terminal portion of each of the leads to corresponding ones of the bonding pads, wherein,
the bonding wires connecting the first plurality of fixed voltage leads to the corresponding bonding pads have an average length B_{PG};
the bonding wires connecting the second plurality of signal leads to the corresponding bonding pads have an average length B_{S}; and further wherein
B_{PG} and B_{S} satisfy the relationship B_{PG}<B_{S}.

2. The semiconductor device according to claim 1, wherein:
the first plurality of fixed voltage leads is configured as lead-on-chip (LOC) leads; and
the second plurality of signal leads is configured as lead-on-chip (LOC) leads.

3. The semiconductor device according to claim 1, wherein:
a ratio of the average lengths B_{PG} and B_{S} is between 1:2 and 1:5.

4. The semiconductor device according to claim 1, wherein:
the first plurality of bonding pads are arranged in a single row.

5. The semiconductor device according to claim 4, wherein:
the single row of bonding pads is arranged along a longitudinal axis of the semiconductor chip.

6. The semiconductor device according to claim 1, wherein:
the first plurality of bonding pads are arranged in two rows, the two rows being parallel and arranged symmetrically on opposite sides of a longitudinal axis of the semiconductor chip.

7. The semiconductor device according to claim 1, wherein:
the first plurality of bonding pads are arranged in three rows,
a first row arranged along a longitudinal axis of the semiconductor chip with the remaining two rows being arranged parallel to the first row and arranged symmetrically on opposite sides of the first row of bonding pads.

8. The semiconductor device according to claim 7, wherein:
the bonding pads arranged in the remaining two rows are signal pads.

9. The semiconductor device according to claim 1, wherein:
the first plurality of bonding pads are arranged in three rows,
a first row arranged along a longitudinal axis of the semiconductor chip with the remaining two rows being arranged perpendicular to the first row and arranged symmetrically at opposite sides of the first row of bonding pads.

10. The semiconductor device according to claim 9, wherein:
the bonding pads arranged in the remaining two rows are signal pads.

11. The semiconductor device according to claim 1, wherein:
portions of the first plurality of fixed voltage leads extend inwardly from the perimeter of the semiconductor chip and over the upper surface of the semiconductor chip by an average length L_{PG}; and
portions of the second plurality of signal leads extend inwardly from the perimeter of the semiconductor chip and over the upper surface by an average length L_{S}; and further wherein
L_{PG} and L_{S} satisfy the relationship L_{PG}>L_{S}.

12. The semiconductor device according to claim 11, wherein:
the relationship B_{PG}+L_{PG}=B_{S}+L_{S} is satisfied.

13. The semiconductor device according to claim 11, wherein:
the relationship B_{PG}+L_{PG}>B_{S}+L_{S} is satisfied.

14. The semiconductor device according to claim 1, wherein:
portions of the first plurality of fixed voltage leads extend inwardly from the perimeter of the semiconductor chip and over the upper surface by an average length L_{PG}; and
no portion of the second plurality of signal leads extends inwardly from the perimeter of the semiconductor chip.

15. The semiconductor device according to claim 1, wherein:
portions of the first plurality of fixed voltage leads extend inwardly from the perimeter of the semiconductor chip and over the upper surface by an average length L_{PG}; and
a subset of leads of the second plurality of signal leads do not include any portion that extends inwardly from the perimeter of the semiconductor chip.

16. The semiconductor device according to claim 1, wherein:
a subset of the first plurality of fixed voltage leads do not include any portion that extends inwardly from the perimeter and across the active surface of the semiconductor chip; and
a subset of leads of the second plurality of signal leads do not include any portion that extends inwardly from the perimeter of the semiconductor chip.

17. The semiconductor device according to claim 1, wherein:
portions of the first plurality of fixed voltage leads extend inwardly from the perimeter of the semiconductor chip and over a first portion of the upper surface, thereby producing an average capacitance C_{PG}; and
portions of the second plurality of signal leads extend inwardly from the perimeter of the semiconductor chip and over a second portion of the upper surface, thereby producing an average capacitance C_{S}; and further wherein
C_{PG} and C_{S} satisfy the relationship C_{PG}>C_{S}.

18. The semiconductor device according to claim 17, wherein:
a ratio of the average capacitances C_{PG} and C_{S} is between 2:1 and 5:1.

19. The semiconductor device according to claim 18, wherein:
at least a subset of leads from the first plurality of fixed voltage leads are configured to increase an average area of the upper surface covered by the subset of leads relative to an average area of the upper surface covered by the remaining fixed voltage leads.

20. The semiconductor device according to claim 18, wherein:
the first plurality of fixed voltage leads include a subset of fixed voltage modified leads having a modified profile that increases an average area of the upper surface covered by the leads.

21. The semiconductor device according to claim 18, wherein:
at least a subset of leads from the first plurality of fixed voltage leads includes a modified profile that increases an average area of the upper surface covered by the subset of leads relative to an average area of the upper surface covered by unmodified fixed voltage leads.

22. The semiconductor device according to claim 18, wherein:
the first plurality of fixed voltage leads includes a modified profile that increases an average area of the upper surface covered by the leads.

23. The semiconductor device according to claim 1, wherein:
none of the bonding wires connecting the first plurality of fixed voltage leads to the corresponding bonding pads extend over any portion of the second plurality of signal leads.

24. The semiconductor device according to claim 1, wherein:
none of the bonding wires connecting the second plurality of signal leads to the corresponding bonding pads extends over any portion of the first plurality of fixed voltage leads.
